(19) United States
(12) Patent Application Publication
(10) Pub. No.: US 2016/0334681 A1
(43) Pub. Date: Nov. 17, 2016

(54) PIXEL STRUCTURE OF LCD PANEL AND METHOD OF MANUFACTURING THEREOF

(71) Applicants: HannStar Display (Nanjing) Corporation Ltd., Nanjing (CN); HannStar Display Corporation Ltd., Taipei (TW)

(72) Inventors: HSIEN-TANG HU, Taipei (TW); MU-KAI KANG, Taipei (TW)

(21) Appl. No.: 15/152,805

(22) Filed: May 12, 2016

(30) Foreign Application Priority Data
May 15, 2015 (CN) 201510251296.9

(51) Int. Cl. G02F 1/1343; G02F 1/1362; G02F 1/1335; G02F 1/1339; H01L 27/12; G02F 1/1368

(52) U.S. Cl. CPC G02F 1/134309; H01L 27/124; H01L 27/1259; G02F 1/1368; G02F 1/133514; G02F 1/1339; G02F 1/136286; G02F 1/13439; G02F 2001/134372

(57) ABSTRACT

A liquid crystal display (LCD) panel comprises a thin film transistor (TFT) array substrate, a color filter substrate and a sealant and a liquid crystal layer. The color filter substrate is disposed on the TFT array substrate. The sealant and a liquid crystal layer are arranged between the TFT array substrate and the color filter substrate, wherein the TFT array substrate includes a pixel structure having a metal layer, a first isolation layer, a first pixel electrode layer, a second pixel electrode layer, and a common electrode layer, the first isolation layer is disposed on the metal layer, the first isolation layer and the common electrode layer directly contact each other, and the first and the second pixel electrode layers are in a pixel unit area.

### CROSS REFERENCE TO RELATED APPLICATION

This application claims the benefit of the Patent Application No. CN 201510251296.9, filed on May 15, 2015, at the China State Intellectual Property Office, the disclosures of which are incorporated herein in their entirety by reference.

### TECHNICAL FIELD

Embodiments in the present disclosure are related to a pixel structure of an LCD panel and a method of manufacturing thereof, and more particularly to a pixel structure of an LCD panel having high transmittance and a method of manufacturing thereof.

### BACKGROUND

Along with the wider, deeper and rapid development of liquid crystal display (LCD) techniques, nowadays the LCDs have overwhelmingly occupied all the main markets for display panel products, such as monitors, mobile phones, televisions, laptops, tablet PCs, global positioning system (GPS) devices, portable video media players, etc.

In an LCD panel, the liquid crystal plays a role of an optical gate, and it controls the transmission of the light and the block of the light in each pixel and/or sub-pixel of the LCD panel during the real-time display. Considering the liquid crystal control mechanism, LCD panels can be classified into two kinds of panels, which are a vertical alignment (VA) panel and a plane switching panel. Because the pixels of the resolution specification of the LCD panel are increasing, the area in each pixel and/or sub-pixel correspondingly becomes smaller. In order to raise the aperture ratio of the pixel and/or sub-pixel, the designer can only strive for more allocated space in the vertical direction of the substrate because the required circuit for each pixel and/or sub-pixel needs to be designed and arranged in a limited area. Therefore, the method of multiple photo-masks is adopted to complete the required circuit gradually, but this increases the required amount of photo-masks and the steps it takes for the manufacturing procedure.

In order to overcome the aforementioned drawbacks in the prior art, the inventor discloses an entire and efficient solution.

### SUMMARY OF EXEMPLARY EMBODIMENTS

In accordance with one embodiment of the present disclosure, a liquid crystal display (LCD) panel is disclosed. The LCD panel includes a thin film transistor (TFT) array substrate, a color filter substrate and a sealant and a liquid crystal layer. The color filter substrate is disposed on the TFT array substrate. The sealant and the liquid crystal layer are arranged between the TFT array substrate and the color filter substrate, wherein the TFT array substrate includes a pixel structure having a metal layer, a first isolation layer, a first pixel electrode layer, a second pixel electrode layer and a common electrode layer, the first isolation layer is disposed on the metal layer, the first isolation layer and the common electrode layer directly contact each other, and the first and the second pixel electrode layers are in a pixel unit area.

In accordance with one embodiment of the present disclosure, a pixel structure for a liquid crystal display (LCD) panel is disclosed. The pixel structure for the LCD panel includes a substrate, a metal layer, a first isolation layer, a common electrode layer, a second isolation layer and a first and a second pixel electrode layers. The metal layer is disposed on the substrate. The first isolation layer is disposed on the metal layer. The common electrode layer is disposed on the first isolation layer, and directly contacts the first isolation layer, the second isolation layer is disposed on the common electrode layer, and the first and the second pixel electrode layers are disposed on the second isolation layer and in a pixel unit area.

In accordance with a further embodiment of the present disclosure, the present invention discloses a method for manufacturing a pixel structure for a liquid crystal display (LCD) panel. The method comprises steps of providing a substrate; and forming a pixel unit on the substrate, wherein forming a pixel unit on the substrate by the further sub-steps of; forming a patterned metal layer on the substrate; forming a first isolation layer on the patterned metal layer; forming a common electrode layer on the first isolation layer and the patterned metal layer; forming a second isolation layer on the common electrode layer; and forming a first pixel electrode layer and a second pixel electrode layer on the second isolation layer

The above embodiments and advantages of the present invention will become more readily apparent to those ordinarily skilled in the art after reviewing the following detailed descriptions and accompanying drawings.

### BRIEF DESCRIPTION OF THE DRAWINGS

FIG. 1 shows a top view of a pixel structure in an FFS LCD according to the preferred embodiment of the present disclosure;

FIG. 2 shows a cross-sectional view of the pixel structure along with an A-A′ line according to the illustration in FIG. 1;

FIG. 3 shows a method diagram of the pixel structure in the FFS LCD according to the preferred embodiment of the present disclosure;

FIG. 4 shows a structure diagram of the FFS LCD panel according to the preferred embodiment of the present disclosure; and

FIG. 5 shows a top view of a pixel unit area according to the preferred embodiment of the present disclosure.

### DETAILED DESCRIPTION OF THE PREFERRED EMBODIMENTS

The present invention is further demonstrated through the following embodiments and Figs, and they can be combined together to form other embodiments. Please note that the detailed descriptions of the following embodiments are not intended to restrict the present invention to any disclosed precise form. In addition, the skilled person in the art can understand that some elements in the Figs. are omitted in order to concisely demonstrate the embodiments of the present invention.

The present invention discloses a pixel structure, wherein a common electrode layer is disposed between a substrate and a pixel electrode layer, and therefore both the appropriate sizes of the line width and the line distance of the pixel electrodes meet the requirements. There is no need to design a smaller line width or line distance, which could easily cause a short circuit or broken circuit.

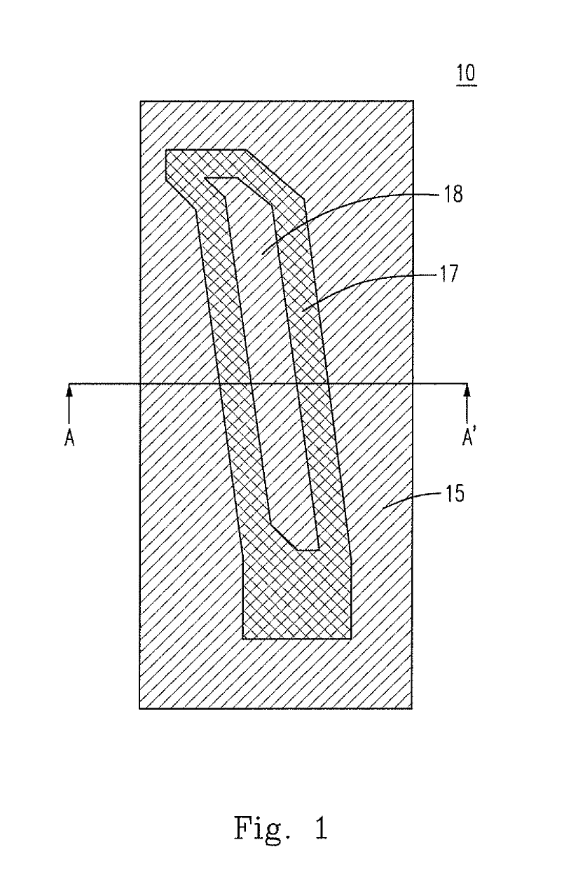

Please refer to FIG. 1, which shows a top view of a pixel structure 10 in a liquid crystal display according to the preferred embodiment of the present disclosure. For example, the liquid crystal display is a fringe field switching (FFS) LCD Viewed in the top-view direction, the pixel structure 10 includes a first electrode layer 15 and a second electrode layer 17 disposed on the first electrode layer 15, wherein the first electrode layer 15 is an entire transparent electrode layer, and serves as a common electrode layer that drives the liquid crystals in the present embodiment. The second electrode layer 17 is a transparent electrode layer having a pattern, and the pattern has a slit 18 in the middle. Because the slit 18 has no transparent electrode layer, the first electrode layer 15 located under the second electrode layer 17 can be directly seen through the slit 18 in the top-view direction, and the second electrode layer 17 serves as a pixel electrode layer that drives the liquid crystals in the present embodiment. Underneath the second electrode layer 17, there are other layers which are not shown in FIG. 1, and the other layers are described in subsequent paragraphs. Regarding the first electrode layer 15 and the second electrode layer 17, there are a variety of shapes and arrangement designs that can be adopted, and so they are not restricted in the present specification.

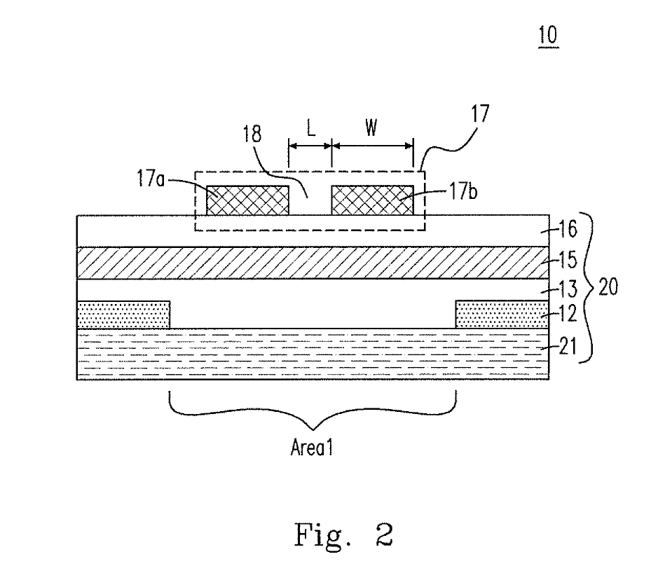

Please refer to FIG. 2, which shows a cross-sectional view of the pixel structure 10 along with the A-A′ line according to the illustration in FIG. 1. The detailed structure of the pixel structure 10 according to the preferred embodiment of the present disclosure can be clearly understood from the illustration in FIG. 2.

The pixel structure 10 includes a substrate 21 and a pixel layer 20 formed on the substrate 21. In some embodiments, the substrate 21 can be a glass substrate or another suitable hard substrate. In another embodiment, the substrate 21 can also be a soft substrate made of a plastic material. The pixel layer 20 includes a metal layer 12 having a circuit (also called a pattern). The metal layer 12 serves as conductive lines, such as data lines 52 shown in FIG. 5. FIG. 5 shows a top view of a pixel unit area Area1 according to the preferred embodiment of the present disclosure. The pixel unit area Area1 is defined by the data lines 52 and gate lines 54. For example, please refer to FIG. 5, the data lines 52 and the gate lines 54 intersect with each other to define the pixel unit area Area1. In some embodiments, the material of the metal layer 12 can be a molybdenum/aluminum/molybdenum layer-like structure (not shown in FIG. 2), and its thickness can be approximately 200 Å/1800 Å/750 Å. Afterwards, a first isolation layer 13 is formed above the metal layer 12. In some embodiments, the material of the first isolation layer 13 can be silicon nitride, silica or silicon oxynitride, and its thickness preferably ranges between 3000 Å to 10000 Å, while the optimal thickness is about 5500 Å. Later, above the isolation layer 13, a transparent conducting layer circuit is formed thereon, i.e., a first electrode layer 15, which serves as a common electrode layer that drives the liquid crystals. In some embodiments, the material of the first electrode layer 15 can be indium tin oxide, indium oxide or tin oxide, its thickness is preferably about 700 Å, and the first electrode layer 15 and the first isolation layer 13 directly contact each other. Later, a second isolation layer 16 having circuits (not shown in FIG. 2 because the circuit is outside FIG. 2) is formed on the first electrode layer 15 using a deposition procedure and a lithography etching procedure. In some embodiments, the material of the second isolation layer 16 can be silicon nitride, silica or silicon oxynitride, and its thickness ranges between about 500 Å to 3000 Å, wherein the optimal thicknesses are about 1500 Å, 2000 Å, or 2500 Å. Finally, a second electrode layer 17 (including layer portions 17a and 17b) is in a pixel unit area Area1 as shown in FIG. 2 and is formed on the second isolation layer 16, and serves as a pixel electrode layer that drives the liquid crystals, wherein the second electrode layer 17 is a transparent conducting layer having a circuit. There are a plurality of pixel unit areas Area1 as shown in FIG. 5, each of which also has the layer portions 17a and 17b in the pixel unit area Area1. In some embodiments, the material of the second electrode layer 17 (including the layer portions 17a and 17b) can be indium tin oxide, indium oxide or tin oxide, and its thickness can be about 700 Å. The layer portions 17a and 17b of the second electrode layer 17 can be spaced apart at a predetermined distance L, and the predetermined distance L ranges between 1.46 μm to 2.0 μm. However, the line width W in each of the layer portions 17a and 17b of the second electrode layer 17 can range between 1.5 μm to 4 μm, which efficiently reduces the possibility of a short circuit and/or broken circuit.

Because the first electrode layer 15 directly contacts the first isolation layer 13, there is no need to arrange a flat layer between the first electrode layer 15 and the isolation layer 13, and thus there is no need to use a photo mask which is made for a protection layer, and there is also no need to perform a sub procedure to form the flat layer.

When the pixel structure 10 is replicated along a row direction and a column direction according to a predetermined pixel array to form a display area of an FFS LCD, its neighborhood two pixel structures 10 are spaced apart at a constant distance, and the predetermined distance L between the layer portions 17a and 17b of the second electrode layer 17 of each the pixel structure 10 can range between 1.46 μm to 2.0 μm as the mentioned before.

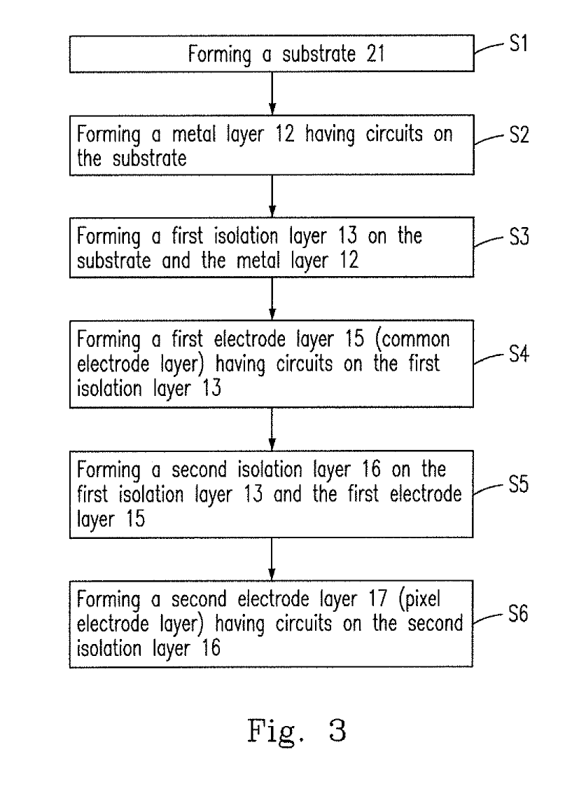

Please refer to FIG. 3, which shows a manufacturing flow diagram of the pixel structure 10 according to the preferred embodiment of the present disclosure. The manufacturing flow diagram as shown in FIG. 3 is described as follows. Step S1: providing a substrate 21. Step S2: forming a metal layer 12 on the substrate 21 through a deposition procedure (such as a sputter coating, a vapor deposition or coating, etc.), and forming the metal layer 12 (also called a patterned metal layer) having circuits using a lithography procedure (including sub procedures of a cleaning process, a photo resist coating process, an exposure and development process (forming a patterned photo resist), an etching process, a de-coating process and a baking process etc.). Step S3: forming a first isolation layer 13 on the substrate 21 and the metal layer 12 using a procedure the same as the aforementioned deposition procedure. Step S4: forming a first electrode layer 15 (also called a patterned first electrode layer 15) having circuits on the first isolation layer 15 using procedures the same as the aforementioned deposition and lithography procedures, and causing the first electrode layer 15 and the first isolation layer 13 to directly contact. Step S5: forming the second isolation layer 16 on the first electrode layer 15 and the first isolation layer 13 using a procedure the same as the aforementioned deposition procedure. Step S6: forming a transparent conducting layer having circuits on the second isolation layer 16 using procedures the same as the aforementioned deposition and lithography procedures, i.e., the second electrode layer 17 (including the layer portions 17a and 17b). Therefore, the pixel structure 10 of the cross-sectional view as shown in FIG. 2 can be obtained.

In addition, according to the design requirements of a practical FFS LCD, a thin film transistor (TFT) array layer 37 or a color filter layer 38 can be further arranged between the substrate 21 and the metal layer 12 as in the subsequent description, and all of them can be additionally arranged with the apposition substrate and the liquid crystals are injected therebetween. After the plurality of procedures, the entire FFS LCD panel structure can be formed.

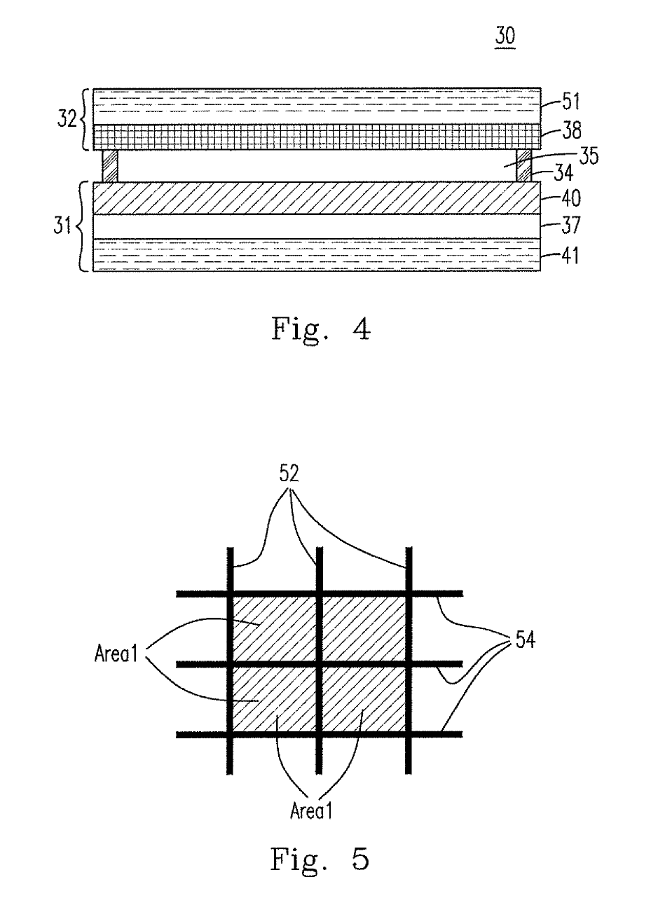

FIG. 4 shows a structural diagram of the FFS LCD panel 30 according to the preferred embodiment of the present disclosure. As shown in FIG. 4, the FFS LCD panel 30 includes a TFT array substrate 31 located at a lower layer, a color filter substrate 32 deposited on a corresponding side of the TFT array substrate 31, a sealant 34 and a liquid crystal layer 35 between the TFT array substrate 31 and the color filter substrate 32, wherein the sealant 34 is fixed to the TFT array substrate 31 and the color filter substrate 32, and defines a scope of the liquid crystal layer 35. The TFT array substrate 31 includes a substrate 41, a pixel structure 40 and a TFT array layer 37. The FFS LCD panel 30 further includes a plurality of gate line 54 and a plurality of data line 52 as shown in FIG. 5 intersecting with other to define a pixel unit area Area1. The color filter substrate 32 includes a substrate 51 and a color filter layer 38, wherein the arrangement of each layer can be altered according to the design of the practical FFS LCD panel, and is not restricted to the above embodiments.

To sum up the above, the present invention has at least the advantages of: reducing production costs, reducing opportunities for short circuits and/or broken circuits, and increasing the production yield rate. In addition, the LCD panel in the embodiments of the present invention has a high transparency. All of these advantages do not restrict the present invention.

### EMBODIMENTS

1. A liquid crystal display (LCD) panel comprises a thin film transistor (TFT) array substrate, a color filter substrate and a sealant and a liquid crystal layer. The color filter substrate is disposed on the TFT array substrate. The sealant and a liquid crystal layer are arranged between the TFT array substrate and the color filter substrate, wherein the TFT array substrate includes a pixel structure having a metal layer, a first isolation layer, a first pixel electrode layer, a second pixel electrode layer, and a common electrode layer, the first isolation layer is disposed on the metal layer, the first isolation layer and the common electrode layer directly contact each other, and the first and the second pixel electrode layers are in a pixel unit area.

2. The LCD panel in Embodiment 1, wherein the TFT array substrate further includes a TFT substrate and the pixel structure is disposed on the TFT substrate.

3. The LCD panel of any one of Embodiments 1-2, wherein the sealant fixes to the TFT array substrate and the color filter substrate, and defines a scope of the liquid crystal layer.

4. The LCD panel of any one of Embodiments 1-3, wherein the LCD panel is a fringe field switching (FFS) LCD panel.

5. The LCD panel of any one of Embodiments 1-4, wherein the pixel structure further includes a first substrate, a second isolation layer. The metal layer is disposed on the first substrate. The second isolation layer is disposed on the common electrode layer. The first and a second pixel electrode layers are disposed on the second isolation layer, wherein the first isolation layer is disposed on the metal layer, and the common electrode layer is disposed on the first isolation layer.

6. The LCD panel of any one of Embodiments 1-5, further comprising a plurality of gate lines, wherein the metal layer includes a plurality of data lines, and the gates lines and the data lines intersect with each other to define the pixel unit area.

7. The LCD panel of any one of Embodiments 1-6, wherein the first isolation layer includes one selected from the group consisting of silicon nitride, silica and silicon oxynitride; the second isolation layer includes one selected from the group consisting of silicon nitride, silica and silicon oxynitride; and each of the first pixel electrode layer and the second pixel electrode layer includes one selected from the group consisting of indium tin oxide, indium oxide and tin oxide.

8. The LCD panel of any one of Embodiments 1-7, wherein the first and the second pixel electrode layers are spaced apart at a distance, ranging between 1.46 μm to 2.0 μm.

9. The LCD panel of any one of Embodiments 1-8, wherein each of the first pixel electrode layer and the second pixel electrode layer has a line width ranging between 1.5 μm to 4 μm.

10. The LCD panel of any one of Embodiments 1-9, wherein the first isolation layer has a first thickness ranging between 3000 Å to 10000 Å, and the second isolation layer has a second thickness ranging between 500 Å to 3000 Å.

11. A pixel structure for a liquid crystal display (LCD) panel comprises a substrate, a metal layer, a first isolation layer, a common electrode layer, a second isolation layer and a first and a second pixel electrode layers. The metal layer is disposed on the substrate. The first isolation layer is disposed on the metal layer. The common electrode layer is disposed on the first isolation layer, and directly contacts the first isolation layer, the second isolation layer is disposed on the common electrode layer, and the first and the second pixel electrode layers are disposed on the second isolation layer and in the pixel unit area

12. The pixel structure in Embodiment 11, wherein the first and the second pixel electrode layers are spaced apart at a distance ranging between 1.46 μm to 2.0 μm.

13. The pixel structure of any one of Embodiment 11-12, wherein the first pixel electrode layer and the second pixel electrode layer have a line width ranging between 1.5 μm to 4 μm.

14. The pixel structure of any one of Embodiment 11-13, wherein the first isolation layer has a thickness ranging between 3000 Å to 10000 Å.

15. The pixel structure of any one of Embodiment 11-14, wherein the second isolation layer has a thickness ranging between 500 Å to 3000 Å.

16. The pixel structure of any one of Embodiment 11-15, wherein the first isolation layer is made of a material being one selected from the group consisting of silicon nitride, silica and silicon oxynitride.

17. The pixel structure of any one of Embodiment 11-16, wherein the second isolation layer is disposed on the common electrode layer, and the second isolation layer is made of a material being one selected from the group consisting of silicon nitride, silica and silicon oxynitride.

18. The pixel structure of any one of Embodiment 11-17, wherein each of the first pixel electrode layer and the second pixel electrode layer is made of a material being one selected from the group consisting of indium tin oxide, indium oxide and tin oxide.

19. A method for manufacturing a pixel structure for a liquid crystal display (LCD) panel, comprising steps of: providing a substrate; and forming a pixel unit on the substrate, wherein forming a pixel unit on the substrate by the further sub-steps of; forming a patterned metal layer on the substrate; forming a first isolation layer on the patterned metal layer; forming a common electrode layer on the first isolation layer and the patterned metal layer; forming a second isolation layer on the common electrode layer; and forming a first pixel electrode layer and a second pixel electrode layer on the second isolation layer.

20. The method in Embodiment 19, further comprising a step of: forming the first pixel electrode layer and the second pixel electrode layer using a lithograph procedure with a distance therebetween, wherein the lithography procedure at least includes steps of: depositing a transparent conducting layer; forming a patterned photo resist on the transparent conducting layer; etching the transparent conducting layer to form the first pixel electrode layer and the second pixel electrode layer; and removing the patterned photo resist.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A liquid crystal display (LCD) panel, comprising:
a thin film transistor (TFT) array substrate;
a color filter substrate; and
a sealant and a liquid crystal layer, arranged between the TFT array substrate and the color filter substrate, wherein the TFT array substrate includes a pixel structure having a metal layer, a first isolation layer, a first pixel electrode layer, a second pixel electrode layer, and a common electrode layer, the first isolation layer is disposed on the metal layer, the first isolation layer and the common electrode layer directly contact each other, and the first and the second pixel electrode layers are in a pixel unit area.

2. The LCD panel as in claim 1, wherein the TFT array substrate further includes a TFT substrate, and the pixel structure is disposed on the TFT substrate.

3. The LCD panel as in claim 1, wherein the sealant fixes thereto the TFT array substrate and the color filter substrate, and defines a scope of the liquid crystal layer.

4. The LCD panel as in claim 1, wherein the LCD panel is a fringe field switching (FFS) LCD panel.

5. The LCD panel as in claim 1, wherein the pixel structure further includes:
a first substrate, wherein the metal layer is disposed on the first substrate;
a second isolation layer disposed on the common electrode layer, wherein
the first and the second pixel electrode layers disposed on the second isolation layer;
wherein the first isolation layer is disposed on the metal layer, and the common electrode layer is disposed on the first isolation layer.

6. The LCD panel as in claim 1, further comprising a plurality of gate lines, wherein the metal layer includes a plurality of data lines, and the gates lines and the data lines intersect with each other to define the pixel unit area.

7. The LCD panel as in claim 5, wherein:
the first isolation layer includes one selected from the group consisting of silicon nitride, silica and silicon oxynitride;
the second isolation layer includes one selected from the group consisting of silicon nitride, silica and silicon oxynitride; and
each of the first pixel electrode layer and the second pixel electrode layer includes one selected from the group consisting of indium tin oxide, indium oxide and tin oxide.

8. The LCD panel as in claim 1, wherein the first and the second pixel electrode layers are spaced apart at a distance ranging between 1.46 μm to 2.0 μm.

9. The LCD panel as in claim 1, wherein each of the first pixel electrode layer and the second pixel electrode layer has a line width ranging between 1.5 μm to 4 μm.

10. The LCD panel as in claim 1, wherein the first isolation layer has a first thickness range ranging between 3000 Å to 10000 Å, and the second isolation layer has a second thickness range ranging between 500 Å to 3000 Å.

11. A pixel structure for a liquid crystal display (LCD) panel, comprising:
a metal layer
a first isolation layer, disposed on the metal layer;
a common electrode layer, disposed on the first isolation layer, and directly contacting the first isolation layer;
a second isolation layer; and
a first and a second pixel electrode layers, the second isolation layer is disposed on the common electrode layer, and the first and the second pixel electrode layers are disposed on the second isolation layer and in a pixel unit area.

12. The pixel structure as in claim 11, wherein the first and the second pixel electrode layers are spaced apart at a distance ranging between 1.46 μm to 2.0 μm.

13. The pixel structure as in claim 11, wherein the first pixel electrode layer and the second pixel electrode layer have a line width ranging between 1.5 μm to 4 μm.

14. The pixel structure as in claim 11, wherein the first isolation layer has a thickness ranging between 3000 Å to 10000 Å.

15. The pixel structure as in claim 11, wherein the second isolation layer has a thickness ranging between 500 Å to 3000 Å.

16. The pixel structure as in claim 11, wherein the first isolation layer is made of a material being one selected from the group consisting of silicon nitride, silica and silicon oxynitride.

17. The pixel structure as in claim 11, wherein the second isolation layer is disposed on the common electrode layer, and is made of a material being one selected from the group consisting of silicon nitride, silica and silicon oxynitride.

18. The pixel structure as in claim 17, wherein each of the first pixel electrode layer and the second pixel electrode layer is made of a material being one selected from the group consisting of indium tin oxide, indium oxide and tin oxide.

19. A method for manufacturing a pixel structure for a liquid crystal display (LCD) panel, comprising steps of:
providing a substrate; and
forming a pixel unit on the substrate, wherein forming a pixel unit on the substrate by the further sub-steps of;
forming a patterned metal layer on the substrate;
forming a first isolation layer on the patterned metal layer;
forming a common electrode layer on the first isolation layer and the patterned metal layer;
forming a second isolation layer on the common electrode layer; and
forming a first pixel electrode layer and a second pixel electrode layer on the second isolation layer.

20. The method as in claim 19, further comprising a step of:
forming the first pixel electrode layer and the second pixel electrode layer using a lithography procedure with a distance therebetween, wherein the lithography procedure at least includes the steps of:
depositing a transparent conducting layer;
forming a patterned photo resist on the transparent conducting layer;
etching the transparent conducting layer to form the first pixel electrode layer and the second pixel electrode layer; and
removing the patterned photo resist.
